(19) United States
(12) Patent Application Publication
(10) Pub. No.: US 2025/0366264 A1
(43) Pub. Date: Nov. 27, 2025

(54) CIRCULAR MICROLEDS FOR LINKS

(71) Applicants: Ivan Huang, Sunnyvale, CA (US); Robert Kalman, Sunnyvale, CA (US); Alexander Tselikov, Sunnyvale, CA (US); Jeff Pepper, Sunnyvale, CA (US); Vahid Mirkhani, Sunnyvale, CA (US)

(72) Inventors: Ivan Huang, Sunnyvale, CA (US); Robert Kalman, Sunnyvale, CA (US); Alexander Tselikov, Sunnyvale, CA (US); Jeff Pepper, Sunnyvale, CA (US); Vahid Mirkhani, Sunnyvale, CA (US)

(21) Appl. No.: 19/203,640

(22) Filed: May 9, 2025

Related U.S. Application Data
(60) Provisional application No. 63/650,142, filed on May 21, 2024.

(51) Int. Cl. H10H 20/819; H10H 20/812

(52) U.S. Cl. CPC H10H 20/819; H10H 20/812

(57) ABSTRACT

A circular microLED with a p portion and an n portion both having circular cross-sections along a common axis. The p portion and the n portion may each have a cylindrical and/or frustoconical shapes. The n portion may have circular cross sections greater than the p portion. The n portion may also have an annular contact. The microLED may be a flip chip microLED, with a p contact within a shell defined by the annular n contact.

### CROSS-REFERENCE TO RELATED APPLICATIONS

This application claims the benefit of U.S. Provisional Patent Application No. 63/650,142, filed on May 21, 2024, the disclosure of which is incorporated by reference herein.

### BACKGROUND OF INVENTION

The desire for high-performance computing and networking is ubiquitous and seemingly ever-present. Prominent applications include data center servers, high-performance computing clusters, artificial neural networks, and network switches.

For decades, dramatic integrated circuit (IC) performance and cost improvements were driven by shrinking transistor dimensions combined with increasing die sizes, summarized in the famous Moore's Law. Transistor counts in the billions have allowed consolidation onto a single system-on-a-chip (SoC) of functionality that was previously fragmented across multiple ICs. However, the benefits of further transistor shrinks are decreasing dramatically as decreasing marginal performance benefits combine with decreased yields and increased per transistor costs. Independent of these limitations, a single IC can only contain so much functionality, and that functionality is constrained because the IC's process cannot be simultaneously optimized for different functionality, for example logic requires a different process than memory and high speed I/O. In fact, there are significant benefits to “de-integrating” SoCs into smaller “chiplets”, including: the process for each chiplet can be optimized to its function; chiplets are well-suited to reuse in multiple designs; and chiplets are less expensive to design.

Chiplets have higher yield because they are smaller with fewer devices. However, a major drawback to chiplets compared to SoCs is that use of chiplets generally requires far more chip-to-chip connections. Compared to the on-chip connections between functional blocks in SoCs, chip-to-chip connections are typically much less dense and require far more power (for example normalized as energy per bit).

Though optics has been a candidate for chip-to-chip interconnects for decades, coupling optical sources and detectors to waveguides (including fibers) frequently dominates the cost of optical links and limits their density for this application.

Optical interconnects based on microLED (μLED) sources may offer a way to overcome some or all of these limitations. A microLED may be generally defined as a LED with a diameter of <100 μm in some embodiments, <20 μm in some embodiments, <4 μm in some embodiments, and <1 μm in some embodiments, and can be made with diameters <1 μm.

However, obtaining desired light output from microLEDs for optical interconnects may be difficult, and microLEDs may have less than desired yields and/or reliability.

For example, lateral microLEDs, with an n portion and a p portion side-by-side, may exhibit current crowding, leading to asymmetric emission of light. Moreover, n portion metal may block emission of light to an undesirable extent. Light extraction efficiency (LEE) may also be reduced due to decreased light emitted from a top surface of the device. Yield and reliability of lateral microLEDs also may be at undesirable levels due to a variety of factors. For example, manufacturing of lateral microLEDs may necessarily be a complicated low-yield process, and poor thermal conductivity to substrates and trade-offs made in the design, shape, and size of n-contacts and p-contacts may lead to reliability issues.

Use of vertical microLEDs, with an n portion and a p portion stacked on one another and contacts on opposing sides of the vertical stack, may also present challenges for Ga face p-contacts with N face n-contacts, especially in high current density applications. Current crowding and n portion metal, even if only at device upper surface edges, may negatively affect emission of light, as with lateral microLEDs. In addition, light exiting over a large area, for example due to a possible large number of internal reflections when thick metal contacts are used for the high current density, may also cause issues. Further, use of indium tin oxide (ITO) for the majority of the upper surface contact may somewhat reduce light emission efficiency, increase electrical resistance, and decrease reliability.

### BRIEF SUMMARY OF THE INVENTION

Some aspects of the invention provide an LED with a circular cross-section, comprising: a p portion with circular cross-sections; an n portion with circular cross-sections, at least some of the circular cross-sections of the n portion having a greater radius than the circular cross-sections of the p portion; a light emitting region including quantum wells between the p portion and the n portion; with centers of the circular cross-sections of the p portion and the n portion defining a common axis; a p contact on a surface of the p portion distal from the n portion; an annular n contact on a surface of the n portion, with the p contact interior to a cylindrical shell defined by the annular n contact.

In some aspects the p contact and the annular n contact are configured to extend in a same direction. In some aspects the p portion is p-doped GaN and the n portion is n-doped GaN. In some aspects the n portion includes at least a frustoconical section, the frustoconical section having a greater radius about the common axis with greater distance from the p portion. In some aspects the frustoconical section forms an angle in a range of 25 to 40 degrees with respect to the common axis. In some aspects the n portion includes a first frustoconical section proximal the p portion and a second frustoconical section distal from the p portion. In some aspects the second frustoconical section of the n portion has greater diameters than the first frustoconical section of the n portion. In some aspects the p portion has a frustoconical shape, the frustoconical shape having diameters less than diameters of the first frustoconical section of the n portion. In some aspects the n portion includes a first cylindrical section proximal the p portion and a second cylindrical section distal from the p portion, the second cylindrical section having a greater diameter than the first cylindrical section. In some aspects the annular n contact is on a surface of the second cylindrical portion.

Some aspects of the invention provide a circular microLED comprising: a cylindrical and/or frustoconical p portion; and a cylindrical and/or frustoconical n portion, the cylindrical and/or frustoconical n portion sharing a common axis with the cylindrical and/or frustoconical p portion; with a greatest diameter of the n portion exceeding a diameter of the p portion about a surface between or demarcating a transition between the p portion to the n portion. In some aspects the p portion is p-doped GaN. In some aspects the n portion is n-doped GaN. In some aspects the n portion includes or forms a cylindrical section. In some aspects the n portion includes or forms a frustoconical section. In some aspects the n portion includes both a frustoconical section and a cylindrical section. Some aspects further comprise a p contact on the p portion and an n contact on the n portion, and wherein the n contact is annular. In some aspects the p contact is interior to a cylindrical shell defined by the annular n contact. In some aspects the n contact and the p contact are both on same direction-facing sides of the microLED. In some aspects the circular microLED is a flip chip microLED.

These and other aspects of the invention are more thoroughly comprehended upon review of this disclosure.

### BRIEF DESCRIPTION OF THE FIGURES

FIG. 1 is a block diagram of a parallel optical interconnect.

FIGS. 2a-b are cross-sectional views of embodiments of optoelectronic subassemblies.

FIGS. 3a-b illustrate cross-sectional views of examples of microlenses to be interposed between optical emitters and an optical coupling assembly.

FIGS. 4a-b are cross-sectionals view of a circular microLED on a substrate, with FIG. 4a a side cross-sectional view and FIG. 4b a cross-sectional view looking upward from just above the substrate.

FIG. 5 shows an example current distribution for the cross-sectional view of FIG. 4b.

FIG. 6 is a side cross-sectional view of a further circular microLED.

FIGS. 7a-b are side cross-sectional views of further embodiments similar to the circular microLED of FIG. 6.

### DETAILED DESCRIPTION

A parallel optical interconnect comprises a plurality of optical communication channels. In some embodiments, each communication channel comprises: an optical transmitter comprising a drive circuit that causes its input electrical signal to be modulated onto the optical output of an optical emitter (e.g., a microLED, LED, or laser); input coupling optics that couple light from the emitter into a first (input) face of an optical transmission medium; an optical transmission medium; output coupling optics that couple light from a second (output) face of the optical transmission medium to an optical receiver; an optical receiver comprising photodetector (PD) coupling optics, a PD, and a receiver circuit that produces an output electrical signal.

In some embodiments of a parallel optical interconnect, the optical emitters are microLEDs. The microLEDs are made from direct gap semiconductors such as GaN/InGaN, InGaAlAs, InGaP, or InGaAsP, in various embodiments. A parallel optical interconnect using microLED optical emitters will be referred to here as a microLED parallel optical interconnect. In some embodiments, the microLEDs are made from GaN/InGaN and emit light at wavelengths in the 400 nm-500 nm range. In some embodiments, the PDs are made from Si. In some embodiments the microLEDs are circular microLEDs.

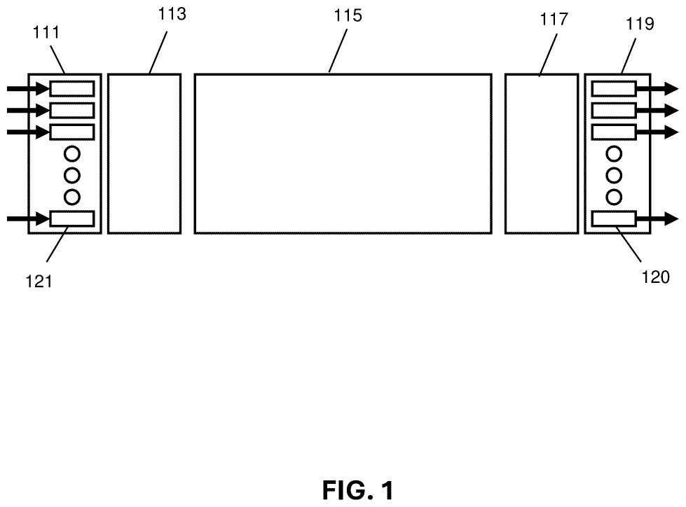

FIG. 1 is a block diagram of a parallel optical interconnect. In some embodiments, the parallel optical interconnect comprises an array of emitters 121 on a substrate 111, an input optical coupling assembly (OCA) 113, a transmission medium 115, an output OCA 117, and an array of photodetectors (PDs) 120 on a substrate 119. In some embodiments, there are no input and output coupling optics, and the emitter and PD arrays may be butt-coupled to the transmission medium. The transmission medium, and the input and output OCAs (if present) optically couple the emitters and PDs. In some embodiments a duplex parallel optical interconnect may be provided, with for example the substrate 111 also including a further array of PDs and the substrate 110 also including a further array of emitters, with the optical transmission medium (or a further optical transmission medium) also optically coupling the further emitters and further PDs. In some embodiments the array of emitters is in a first semiconductor package, and the array of PDs is in a second semiconductor package. In some embodiments the array of emitters and the array of PDs are in a same semiconductor package. In some embodiments the transmission medium is a plurality of optical fibers, in some embodiments arranged in a fiber bundle. In the subsequent description, the term “optoelectronic device array” (or “OE device array”) may refer to an optical emitter array or a PD array.

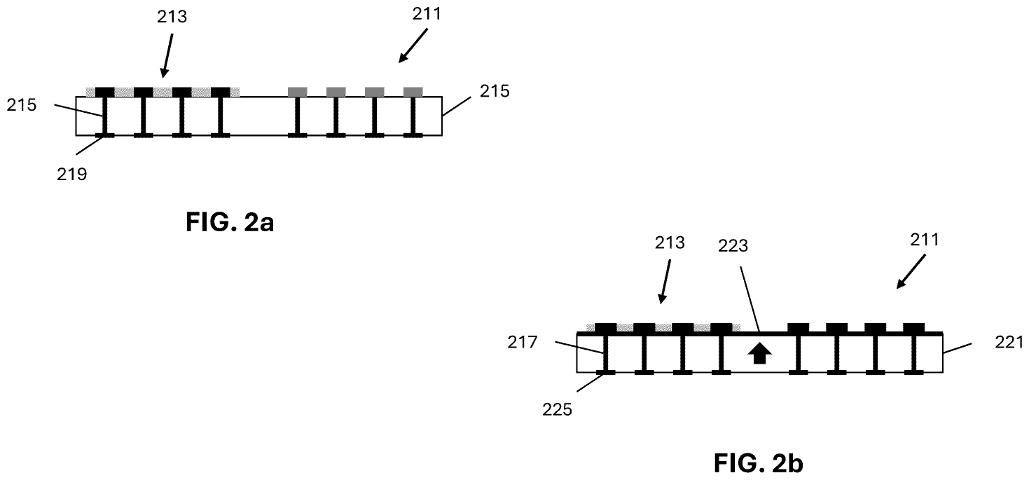

In some embodiments the substrates are each mounted to a corresponding semiconductor integrated circuit chip. FIGS. 2a-b are cross-sectional views of embodiments of optoelectronic subassemblies For example, in FIG. 2a, an emitter array 211 and a PD array 213 may be each mounted to a first surface of a passive substrate 215. The passive substrate may include vias 217, for example through-silicon vias (TSVs) if the substrate is silicon. The TSVs electrically couple the emitters and the PDs to an opposing surface of the substate, for example to electrical pads 219 on or in the opposing surface of the substrate. The opposing surface of the substrate may be mounted to a semiconductor integrated circuit chip, which may include driver circuitry for the emitters and receive circuitry for the PDs.

In some embodiments the substrate 111 and the substrate 119 are each a semiconductor integrated circuit chip. For example, in FIG. 2b, the emitter array 211 and the PD array 213 may be each mounted to a first surface of a semiconductor integrated circuit chip 221. The semiconductor integrated circuit chip may include circuitry 223 in an active layer. The active layer may be about the first surface of the semiconductor integrated circuit chip, for example as illustrated in FIG. 2b. The circuitry may include transmit circuitry, for example emitter drivers, and receive circuitry, for example TIAs. In some embodiments the emitter drivers may be directly under the emitters, or directly under an area defined by the emitter array. In some embodiments the TIAs may be directly under the PDs, or directly under an area defined by the PD array. The circuitry is electrically coupled to an opposing surface, for example electrical pads 225 of the semiconductor integrated circuit chip by TSVs 217.

In some embodiments, the array of emitters and the array of PDs are located on some regular grid. In some embodiments, the emitter and PD grids are hexagonal close-packed (HCP), square, or rectangular grids. In some embodiments, the center-to-center spacing of grid elements are in the range of 10 μm-100 μm.

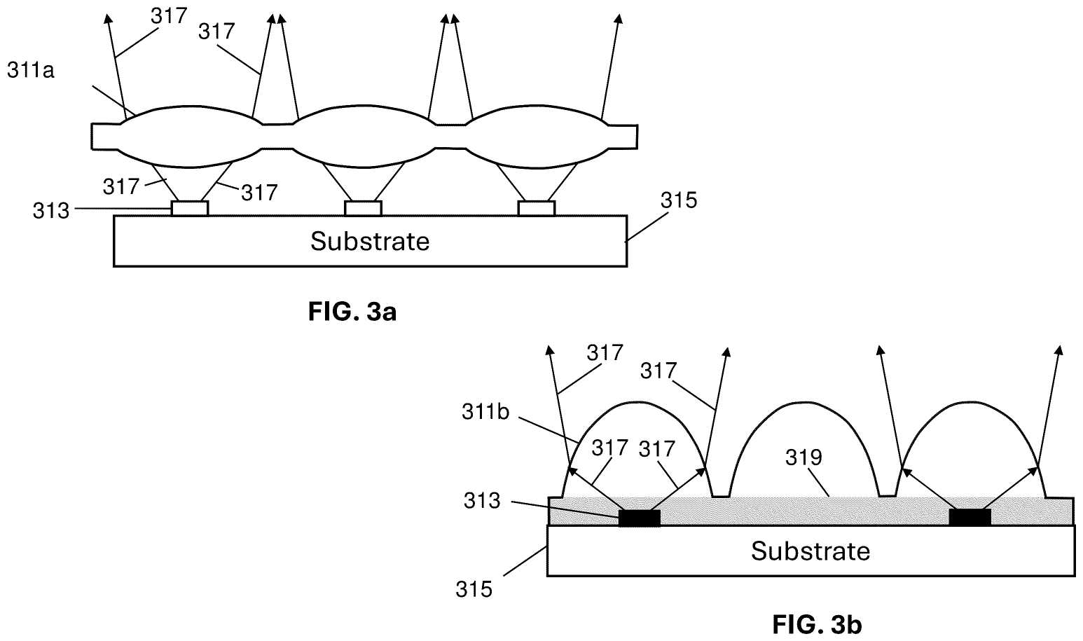

In some embodiments, a microlens is interposed between each emitter and the input optical coupling assembly (OCA). In some embodiments the microlenses comprise the input OCA. FIGS. 3a-b illustrate cross-sectional views of examples of microlenses to be interposed between optical emitters and an optical coupling assembly. In FIGS. 3a-b, a microlens 311a,b is shown for each emitter 313. The emitters are on a substrate 315. The output angular optical distribution from each microlens is narrower than that from the emitter, for example as illustrated by output light rays 317 in FIG. 3a,b. Having the reduced output angular optical distribution can allow for reduction in OCA diameter and coupling losses to a transmission medium. In some embodiments, a microlens is interposed between the output OCA and each PD, where each microlens focuses the light incident on it onto its associated PD, e.g., the emitters shown in FIG. 2a,b may be replaced by PDs, with the direction of light generally reversed to have light arrive at the PDs. In some embodiments, the microlenses are part of a microlens array that is positioned approximately one microlens focal length from the OE device array, for example as illustrated in FIG. 3a. In some embodiments, the microlens array is attached to the OE device array such that the OE device array is embedded in a medium 319 with a similar refractive index to the microlenses, for example as shown in FIG. 3b.

In some embodiments of a parallel optical interconnect, the optical transmission medium for each channel comprises an optical waveguide, for instance an optical fiber or a planar optical waveguide. In some embodiments of a parallel optical interconnect, the transmission medium comprises an array of optical fibers (a fiber “bundle”) or an array of optical waveguides. A FOB comprises multiple fiber elements (FEs) that are packed into a bundle and comprises two optical “faces” at the two ends of the FOB where light is coupled into and out of the FOB. Each FE comprises a core surrounded by a concentric cladding layer with a lower index of refraction than the core, enabling the guiding of light in the core. In some embodiments, FEs in a FOB may be arranged in a regular pattern such as a square grid or a hexagonal grid. In some embodiments of a FOB, the positions of each FE relative to the other FEs is the same at each packing segment such that the FE positions are not “mixed” at each packing segment. An FOB in which the relative positions of the FEs are preserved is referred to as a “coherent” FOB. In some embodiments, the grid pattern of the FEs in a FOB matches that of the emitter array and PD array elements. In some embodiments, the FEs are on a finer grid than the emitter and PD array elements such that each emitter and PD couples to more than one FE in the FOB.

In some embodiments, a circular microLED includes a cylindrical and/or frustoconical p portion and a cylindrical and/or frustoconical n portion, with a greatest diameter of the n portion exceeding a diameter of the p portion about a surface demarcating a transition from the p portion to the n portion. In some embodiments the p portion is p-doped GaN. In some embodiments the n portion is n-doped GaN. In some embodiments the n portion includes or forms a cylindrical section. In some embodiments the n portion includes or forms a frustoconical section. In some embodiments the n portion includes both a frustoconical section and a cylindrical section. In some embodiments the conical cylindrical section of the n portion extends from the p portion. In some embodiments an n contact, or pad, for the n portion, is with the n contact in the form of a ring. In some embodiments the n contact is annular. In some embodiments a p contact, for the p portion, is within a cylindrical shell defined by the annular n contact. In some embodiments the p contact is interior to a cylindrical shell defined by the annular n contact. In some embodiments the n contact and the p contact are both on same direction-facing sides of the microLED. In some embodiments the circular microLED is a flip chip microLED.

In some embodiments, a circular microLED includes an n contact, or pad, for an n portion, with the n contact in the form of a ring. In some embodiments the n contact is annular. In some embodiments a p contact, for a p portion, is within a cylindrical shell defined by the annular p contact. In some embodiments the n contact is interior to a cylindrical shell defined by the annular p contact. In some embodiments the p contact and the n contact are both on same direction-facing sides of the microLED. In some embodiments the circular microLED is a flip chip microLED. In some embodiments the n portion is cylindrical and/or frustoconical and the n portion is cylindrical and/or frustoconical, with a greatest diameter of the n portion exceeding a diameter of the p portion about a surface demarcating a transition from the p portion to the n portion. In some embodiments the n portion includes or forms a cylindrical section. In some embodiments the n portion includes or forms a frustoconical section. In some embodiments the n portion includes both a frustoconical section and a cylindrical section. In some embodiments the conical section is a frustoconical section. In some embodiments the conical cylindrical section of the n portion extends from the p portion. In some embodiments the p portion is p-doped GaN. In some embodiments the n portion is n-doped GaN.

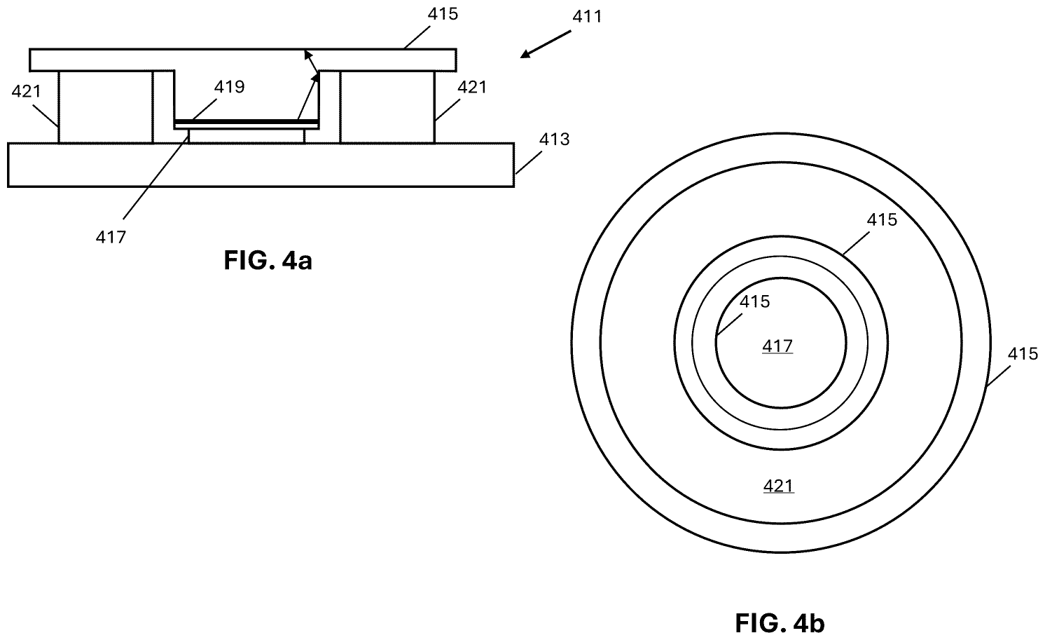

FIG. 4a is a side cross-sectional view of a circular microLED 411 on a substrate 413, in accordance with aspects of the invention. FIG. 4b is a cross-sectional view of the circular microLED of FIG. 4a, looking upward from just above the substrate. The substrate may be a silicon substrate. The silicon substrate may include TSVs or other metallization to allow for electrical connections to the p portion (for example by way of the p contact). In some embodiments the substrate may be a substrate as discussed with respect to FIG. 2a or FIG. 2b.

The microLED of FIG. 4a,b includes a p portion 417, with an n portion 415 above the p portion. The p portion may be p-doped GaN, and the n portion may be n-doped GaN. A light emitting region 419, for example including quantum wells, is between the p portion and the n portion. In FIG. 4a the p portion is shown as being on the substrate. In most embodiments a p contact, for example of a metal, is between the p portion and the substrate. The p contact may, for example, have a cross section, parallel to the substrate, in circular form. The p contact is omitted from FIG. 4a for clarity. In the embodiment of FIG. 4a,b, the circular microLED may be considered to include a cylindrical p portion and a cylindrical n portion, with a greatest diameter of the cylindrical n portion exceeding a diameter of the cylindrical p portion about a surface demarcating a transition from the p portion to the n portion.

In FIGS. 4a and 4b, the p portion is shown as having a cylindrical shape, with a base of the cylinder on the substrate. The n portion has a stepped cylindrical shape, with a first section of the stepped cylindrical shape having a diameter less than a second section of the stepped cylindrical shape. The first section and the second section share a cylindrical axis. In FIG. 4b, the first section has a greater length along the cylindrical axis than the second section, providing the stepped cylindrical shape a somewhat T-shaped cross-section. In other embodiments, the first section and the second section may have equal lengths along the cylindrical axis, or the second section may have a greater length than the first section.

For the n portion, a base of the first section of the stepped cylindrical shape is on what may be viewed in FIG. 4a as a top of the cylindrically shaped p portion. The second section of the stepped cylindrical shape extends from and above (as viewed in FIG. 4a) the first section. As the second section has a greater diameter than the first section, the second section also extends outward from edges of a cylinder of infinite length defined by the first section. In the embodiment of FIG. 4a,b, the second section has a diameter approximately three times the diameter of the first section, and a length along the cylindrical axis approximately one quarter that of the first section.

The n portion also includes an n contact 421. The n contact extends from a lower side (as viewed in FIG. 4a) of the second section of the n portion to the substrate. The substrate may include TSVs or other metallization to allow for electrical connections to the n contact.

The n contact is in the form of a cylindrical shell. The p contact (not shown in FIG. 4a,b) would be concentrically within the n contact. In FIG. 4a,b, the cylindrical shell is shown as having a width approximately three quarters of a width of the first section of the n section and having inner and outer edges approximately equidistant from the outer edges of the first section of the n portion and outer edges of the second section of the n portion, respectively.

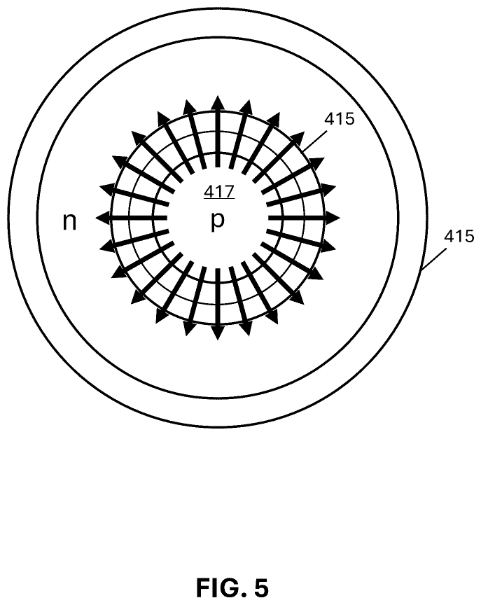

FIG. 5 repeats FIG. 4b, with current distribution also shown by arrows within the figure. In FIG. 5, current is shown as flowing radially outward, in a uniform manner, from the p portion to the n contact of the n portion. With uniform current spreading, current crowding may be reduced.

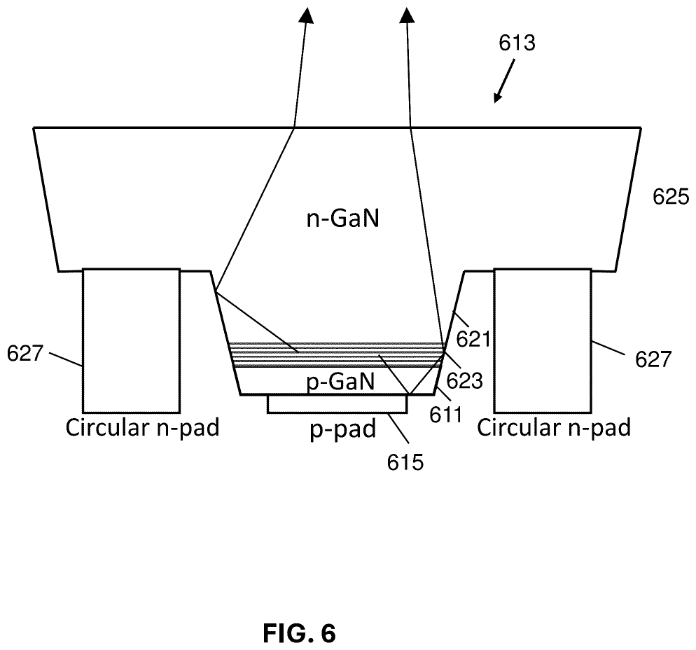

FIG. 6 is a side cross-sectional view of a further circular microLED, in accordance with aspects of the invention. The embodiment of FIG. 6, like the embodiment of FIG. 4a,b includes a p portion 611, with an n portion 613 above the p portion. The p portion may be p-doped GaN, and the n portion may be n-doped GaN, with FIG. 6 labeling the p portion as p-GaN and the n portion as n-GaN.

In FIG. 6 the p portion is shown as being on a p contact 615, which may be referred to as a p pad. In some embodiments the p contact is metal. The p contact provides for an electrical connection to the p portion and may be in contact with metallization of a substrate (not shown in FIG. 6), for example as discussed with respect to the embodiment of FIG. 4a,b. In some embodiments the p contact is in the form of a cylinder, with for example the p portion extending from a top of the cylinder. The height of the cylinder may be very small, compared to a diameter of the cylinder. For example, the diameter of the cylinder may be ten times, or more, the height of the cylinder. In some embodiments the height of the cylinder of the p contact may be in the same order of magnitude as the height of the p portion.

The p portion has a generally frustoconical shape, with increasing diameter with increasing distance from the p contact. A first section 621 of the n portion continues above the p portion, with the first section of the n portion also having a generally frustoconical shape with increasing diameter with distance from the n portion. The frustoconical shape of the first section shares a common axis with the frustoconical shape of the p portion. A multiple quantum well (MQW) structure 623 is provided between the p portion and the first section of the n portion. As illustrated, the MQW structure and the first section of the n portion continue the frustoconical shape of the n portion, such that the n portion, the MQW structure, and the p portion may all be considered to provide a single frustoconical shape.

The frustoconical shape of both the first section of the n portion and the p portion may be considered as forming an inverted mesa, with the p portion being the top of the mesa. The mesa sidewalls are angled, for example 30 degrees from vertical, when viewed as in FIG. 6. In some embodiments the mesa sidewall angle is in the range of 25 to 40 degrees from vertical. It is believed that such angling of the mesa sidewall increases reflection of light from the mesa sidewall optimally for coupling into a microlens and ultimately into a fiber that may be positioned above the circular microLED. In some embodiments the mesa sidewall may instead be shaped to approximate a compound parabolic concentrator. In some embodiments the n portion is deposited on a substrate, for example a sapphire substrate, with the p portion later added. Etching steps may be provided as appropriate to obtain desired shapes, and the sapphire substrate may be later removed.

The n portion also includes a second section 625, above the first section. The second section is shown as also having a frustoconical shape with a smallest diameter significantly larger than a greatest diameter of the first section. In various embodiments the second section may instead be cylindrical. In either case, the frustoconical shapes of the second section and the first section share a common axis, also shared with the frustoconical shape of the p portion. In FIG. 6, the smallest diameter of the second section is shown as being about twice the greatest diameter of the first section. In FIG. 6, the second section has a length along the frustoconical axis approximately the same as a length along the frustoconical axis of the first section and p portion combined. In some embodiments these lengths may each be 2.5 μm.

Then portion also includes an n contact 627. As with the embodiment of FIG. 4a,b, the n contact is in the form of a cylindrical shell that extends from a lower side (as viewed in FIG. 6) of the second section of the n portion to the substrate. The substrate may include TSVs or other metallization to allow for electrical connections to the n contact.

The embodiment of FIG. 6 is therefore similar to the embodiment of FIG. 4a,b. For example, both circular microLEDs are flip-chip type LEDs, with a p contact and an n contact on faces facing towards a same substrate; both have p and n portions with a circular cross-section (in directions looking upward with respect to FIGS. 4a and 6); both have the n portion on top of the p portion (as viewed in FIGS. 4a and 6); and both have a cylindrical shell n contact concentrically around a p contact. The embodiment of FIG. 6, however, additionally includes angled sidewalls for the inverse mesa formed of the first section of the n portion and the p portion.

In fabrication, both the embodiments of FIG. 4a,b and FIG. 6 may be formed by epitaxially growing the n portion and p portion on a substrate, for example a sapphire substrate, with the contacts subsequently deposited, and etching steps utilized in providing a desired profile. The sapphire substrate may be removed prior to use, either before or after the embodiments are coupled to a substrate with electrical connections for the p and n contacts.

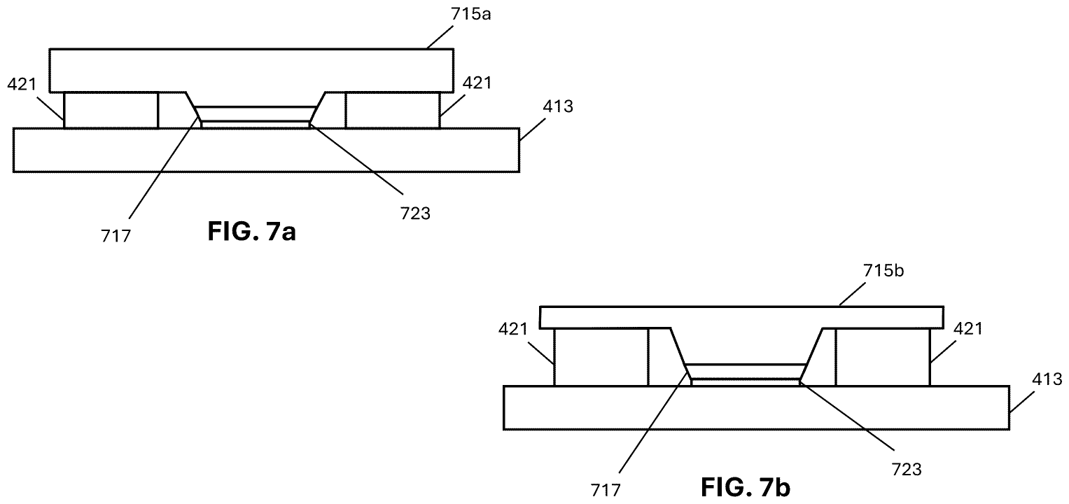

FIGS. 7a and 7b are side cross-sections of embodiments similar to that of FIG. 6. The embodiment of FIG. 7a includes a cylindrical p contact 723 on the substrate 413. A p portion 717 having a frustoconical shape is on the p contact, with the p portion having a diameter increasing with distance from the substrate. A first section of an n portion 715a extends above the p portion, with the first section again having a frustoconical shape sharing a common axis with the frustoconical shape of the p portion. A second section of the n portion has a cylindrical shape, also sharing the same common axis. As with the previously discussed embodiments, the n contact 421 is in the form of a cylindrical shell, extending between the second portion of the n portion and the substrate. Unlike the embodiment of FIG. 6, the first section of the n portion has a length along the common cylindrical axis about that of the n portion, while the second section has a greater length along the axis.

For the embodiment of FIG. 7b, relative length along the common axis of the first section of an n portion 715b and the second section of the n portion are reversed as compared to the embodiment of FIG. 7a. In the embodiment of FIG. 7b, the first section has a longer length along the axis, for example three times the length of the section along the axis.

Although aspects of the invention have been discussed with respect to particular embodiments, it should be understood that the invention comprises the claims supported by this disclosure.

What is claimed is:

1. An LED with a circular cross-section, comprising:
a p portion with circular cross-sections;
an n portion with circular cross-sections, at least some of the circular cross-sections of the n portion having a greater radius than the circular cross-sections of the p portion;
a light emitting region including quantum wells between the p portion and the n portion;
with centers of the circular cross-sections of the p portion and the n portion defining a common axis;
a p contact on a surface of the p portion distal from the n portion;
an annular n contact on a surface of the n portion, with the p contact interior to a cylindrical shell defined by the annular n contact.

2. The circular microLED of claim 1, wherein the p contact and the annular n contact are configured to extend in a same direction.

3. The circular microLED of claim 1, wherein the p portion is p-doped GaN and the n portion is n-doped GaN.

4. The circular microLED of claim 1, wherein the n portion includes at least a frustoconical section, the frustoconical section having a greater radius about the common axis with greater distance from the p portion.

5. The circular microLED of claim 4, wherein the frustoconical section forms an angle in a range of 25 to 40 degrees with respect to the common axis.

6. The circular microLED of claim 1, wherein the n portion includes a first frustoconical section proximal the p portion and a second frustoconical section distal from the p portion.

7. The circular microLED of claim 6, wherein the second frustoconical section of the n portion has greater diameters than the first frustoconical section of the n portion.

8. The circular microLED of claim 7, wherein the p portion has a frustoconical shape, the frustoconical shape having diameters less than diameters of the first frustoconical section of the n portion.

9. The circular microLED of claim 1, wherein the n portion includes a first cylindrical section proximal the p portion and a second cylindrical section distal from the p portion, the second cylindrical section having a greater diameter than the first cylindrical section.

10. The circular microLED of claim 9, wherein the annular n contact is on a surface of the second cylindrical portion.

11. A circular microLED comprising:
a cylindrical and/or frustoconical p portion; and
a cylindrical and/or frustoconical n portion, the cylindrical and/or frustoconical n portion sharing a common axis with the cylindrical and/or frustoconical p portion;
with a greatest diameter of the n portion exceeding a diameter of the p portion about a surface between or demarcating a transition between the p portion to the n portion.

12. The circular microLED of claim 11, wherein the p portion is p-doped GaN.

13. The circular microLED of claim 11, wherein the n portion is n-doped GaN.

14. The circular microLED of claim 11, wherein the n portion includes or forms a cylindrical section.

15. The circular microLED of claim 11, wherein the n portion includes or forms a frustoconical section.

16. The circular microLED of claim 11, wherein the n portion includes both a frustoconical section and a cylindrical section.

17. The circular microLED of claim 11, further comprising a p contact on the p portion and an n contact on the n portion, and wherein the n contact is annular.

18. The circular microLED of claim 17, wherein the p contact is interior to a cylindrical shell defined by the annular n contact.

19. The circular microLED of claim 17, wherein the n contact and the p contact are both on same direction-facing sides of the microLED.

20. The circular microLED of claim 17, wherein the circular microLED is a flip chip microLED.
